(19) United States
(12) Patent Application Publication
(10) Pub. No.: US 2025/0231248 A1
(43) Pub. Date: Jul. 17, 2025

(54) METHOD FOR ESTIMATING BATTERY CAPACITY AND METHOD FOR ESTIMATING BATTERY SOC

(71) Applicant: Toyota Jidosha Kabushiki Kaisha, Toyota-shi (JP)

(72) Inventor: Takayuki MIYAJIMA, Nagoya-shi (JP)

(73) Assignee: Toyota Jidosha Kabushiki Kaisha, Toyota-shi (JP)

(21) Appl. No.: 18/950,840

(22) Filed: Nov. 18, 2024

(30) Foreign Application Priority Data
Jan. 17, 2024 (JP) 2024-005125

(51) Int. Cl. G01R 31/387; G01R 31/36; G01R 31/374; G01R 31/389; H01M 10/44

(52) U.S. Cl. CPC G01R 31/387; G01R 31/3648; G01R 31/374; G01R 31/389; H01M 10/443

(57) ABSTRACT

An object of the present disclosure is to provide a method for accurately estimating battery capacity, and a method for accurately estimating SOC of battery based on the estimated battery capacity determined by such a method for estimating battery capacity. The method of the present disclosure for estimating battery capacity, comprises having a computer execute the following steps: (a) determining a specific internal resistance, in a prescribed provisional SOC of 80% or more and a prescribed temperature, by charging at a prescribed charging speed for a prescribed time; and (b) determining an estimated battery capacity from the specific internal resistance based on a pre-specified first relationship between the specific internal resistance and battery capacity. The method of the present disclosure for estimating battery SOC comprises, after step (b), having a computer execute determining an estimated amount of change in SOC or an estimated SOC after change associated with battery degradation.

### FIELD

The present disclosure relates to a method for estimating battery capacity and a method for estimating battery SOC.

### BACKGROUND

Techniques for estimating state of charge (SOC) based on open circuit voltage (OCV) of a battery are known.

For example, PTL 1 discloses an SOC estimation device and an SOC estimation method that estimates an SOC-OCV characteristic closer to a true value depending on the implementation status of charging and discharging in response to fluctuations in the SOC-OCV characteristic due to a charging and discharging history, estimates SOC using the estimated SOC-OCV characteristic, and can reduce an estimation error of the SOC.

### CITATION LIST

### Patent Literature

[PTL 1]. JP 2014-059206 JP

### SUMMARY

### Technical Problem

Although various other methods for estimating SOC are known, methods for accurately estimating SOC are still desired.

In addition to being able to accurately estimate SOC of battery, it is also desirable to be able to accurately estimate battery capacity.

An object of the present disclosure is to provide a method for accurately estimating battery capacity, and a method for accurately estimating SOC of battery based on the estimated battery capacity determined by such a method for estimating battery capacity.

### Solution to Problem

The present disclosers have discovered that the above object can be achieved by the following means.

### <Aspect 1>

A method for estimating battery capacity, comprising having a computer execute the following steps:
(a) determining a specific internal resistance by charging at a prescribed charging speed for a prescribed time at a prescribed provisional SOC of 80% or more and at a prescribed temperature; and
(b) determining an estimated battery capacity from the specific internal resistance based on a pre-specified first relationship between the specific internal resistance and battery capacity.

### <Aspect 2>

A method for estimating battery SOC, comprising, after step (b) in the method according to Aspect 1, having a computer execute the following steps:
(i) determining an estimated amount of change in SOC associated with battery degradation from the estimated battery capacity based on a pre-specified second relationship between the estimated battery capacity and an amount of change in SOC associated with battery degradation, or
(ii) determining an estimated SOC after change associated with battery degradation from the estimated battery capacity based on a pre-specified third specific relationship between the estimated battery capacity and SOC after change associated with battery degradation.

### <Aspect 3>

The method according to Aspect 1 or 2,
wherein the first relationship has a primary formula, and
wherein coefficient of determination of the primary formula is 0.8 or more,

### <Aspect 4>

The method according to Aspect 1 or 2,
wherein the prescribed time is 20 seconds or more, and
wherein the prescribed charging speed is 3C or more.

### Advantageous Effects of Invention

According to the present disclosure, a method for accurately estimating battery capacity, and a method for accurately estimating SOC of battery based on the estimated battery capacity determined by such a method for estimating battery capacity can be provided.

### BRIEF DESCRIPTION OF DRAWINGS

FIG. 1 is a flow chart of the method of the present disclosure for estimating battery capacity and SOC.

FIG. 2 is a conceptual diagram of a map showing the relationship between the specific internal resistance and the battery capacity.

FIG. 3 is a conceptual diagram of a map showing the relationship between the estimated battery capacity and the amount of change in SOC associated with battery degradation.

FIG. 4 is an exemplary graph of SOC-OCV curves before and after the durability test.

FIG. 5 is a graph showing the relationship between the specific internal resistance and the battery capacity at each provisional SOC.

FIG. 6 is a graph showing the relationship between the provisional SOC and the coefficient of determination R² of the map showing the relationship between the specific internal resistance and the battery capacity.

FIG. 7 is a graph showing the relationship between the battery voltage and the voltage derivative of capacity (dQ/dV) when two batteries whose battery capacities became different due to degradation are charged at a prescribed condition.

### DESCRIPTION OF EMBODIMENTS

Hereinafter, embodiments of the present disclosure will be described in detail. It should be noted that the present disclosure is not limited to the following embodiments, and various modifications can be made thereto within the scope of the disclosure.

### «Method for Estimating Battery Capacity»

The method of the present disclosure for estimating battery capacity, comprises having a computer execute the following steps: (a) determining a specific internal resistance, in a prescribed provisional SOC of 80% or more and a prescribed temperature, by charging at a prescribed charging speed for a prescribed time; and (b) determining an estimated battery capacity from the specific internal resistance based on a pre-specified first relationship between the specific internal resistance and battery capacity.

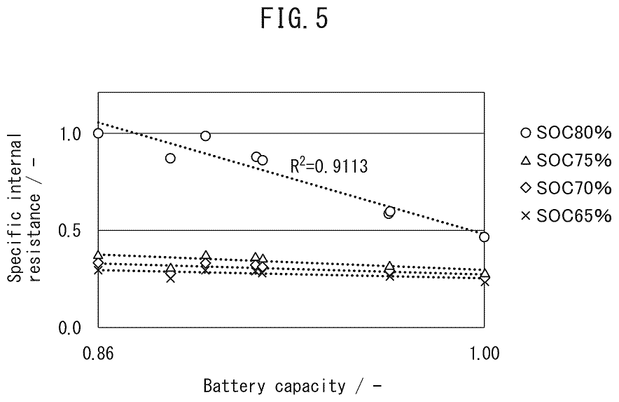

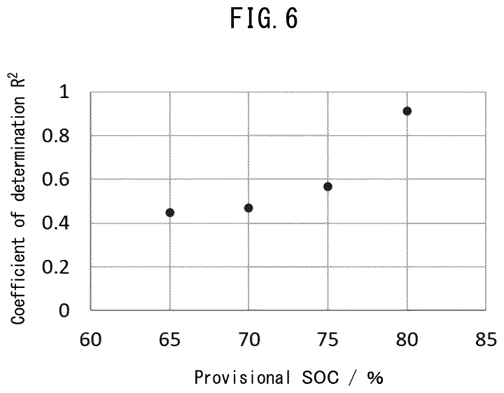

As shown in FIGS. 5 and 6, according to the studies of the present disclosers, the coefficient of determination of a primary formula showing the relationship between the internal resistance (specific internal resistance) of a battery measured by charging at a prescribed condition in which a provisional SOC was 80% or more and the battery capacity was 0.8 or more. That is, in this case, the specific internal resistance and the battery capacity showed a high correlation. Thus, the present disclosers have found that the battery capacity can be accurately estimated from specific internal resistance. That is, although the measurement conditions are limited, the method of the present disclosure can accurately estimate the battery capacity.

In contrast, as also shown in FIGS. 5 and 6, the coefficient of determination of a primary formula showing the relationship between the specific internal resistance of a battery measured by charging at a prescribed condition in which a provisional SOC was less than 80% and the battery capacity was less than 0.8. That is, in this case, the correlation between the specific internal resistance and the battery capacity was low.

In FIG. 5, the values of specific internal resistance and battery capacity are shown as relative values with the maximum value of each measurement being 1.0.

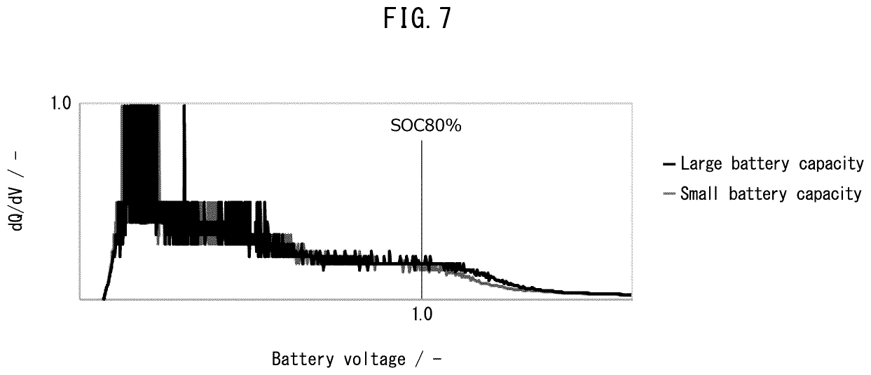

FIG. 7 shows the relationship between the battery voltage (V) and the voltage derivative of capacity (dQ/dV) when two batteries whose battery capacities became different due to degradation are charged for 5 seconds with CC charging at 1C. As shown in FIG. 7, when charging was executed at a battery voltage corresponding to a provisional SOC of 80% or more, the difference in the voltage derivative of capacity (dQ/dV) could be accurately distinguished for the two batteries whose battery capacities became different due to degradation (see the right side of the straight line indicating “SOC80%” in FIG. 7).

That is, as shown in FIG. 7, when charging at a battery voltage corresponding to a provisional SOC of 80% or more, it was possible to separate the dQ/dV curve of a battery whose battery capacity became small due to degradation (a battery with a “small battery capacity”) and the dQ/dV curve of a battery whose battery capacity remained large without becoming small due to degradation (a battery of a “large battery capacity”). Here, the voltage derivative of the capacity (dQ/dV) means the battery capacity at each voltage. Therefore, as shown in FIG. 7, when charging was executed at the battery voltage corresponding to the provisional SOC of 80% or more, the difference between the battery capacity of the battery whose battery capacity became small due to degradation (the battery of the “small battery capacity”) and the battery capacity of the battery whose battery capacity remained large without becoming small due to degradation (the battery of the “large battery capacity”) was clear. That is, FIG. 7 suggests that there is also a correlation between the battery voltage and the battery capacity.

In contrast, as also shown in FIG. 7, when charging was executed at a battery voltage corresponding to a provisional SOC of less than 80%, it was not possible to distinguish the difference in between the battery capacity of the battery whose battery capacity became small due to degradation (the battery of the “small battery capacity”) and the battery capacity of the battery that remained large without becoming small due to degradation (the battery of the “large battery capacity”) (see the left side of the straight line indicating “SOC80%” in FIG. 7).

In FIG. 7, the value of dQ/dV is shown as a relative value with the maximum value of the measured value taken as 1.0, and the value of the battery voltage is shown as a relative value with the case of SOC of 80% taken as 1.0.

Regarding to the present disclosure, the “provisional SOC” means SOC measured or estimated prior to step (a).

The prescribed provisional SOC may be 80% or more, 85% or more, 90% or more, or 95% or more, and may be less than 100%, 95% or less, 90% or less, 85% or less, or 80% or less.

Regarding to the present disclosure, “specific internal resistance” means an internal resistance of a battery measured, in a prescribed provisional SOC of 80% or more and a prescribed temperature, by charging at a prescribed charging speed for a prescribed time.

Regarding to the method of the present disclosure, the first relationship has a primary formula, and the coefficient of determination of the primary formula R² may be 0.8 or more. The coefficient of determination R² is the squared value of the coefficient of correlation R, and the closer it is to 1.0, the higher the correlation between the specific internal resistance and the battery capacity, and the higher the degree of fit of the regression equation. Here, the first relationship with a primary formula may be, for example, a map showing the relationship between the specific internal resistance and the battery capacity.

As shown in FIGS. 5 and 6, according to the study by the present disclosers, when the provisional SOC was 80% or more, the coefficient of determination R² was more than 0.8. In contrast, when the provisional SOC was less than 80%, the coefficient of determination R² was less than 0.8. Specifically, when the provisional SOC was 75%, the coefficient of determination R² was 0.6 or less, and when the provisional SOC was 70% and 65%, the coefficient of determination R² was 0.5 or less. That is, when the provisional SOC is 80% or more, the correlation between the specific internal resistance and the battery capacity becomes high, and thus the estimated battery capacity can be accurately determined.

The prescribed time may be 20 seconds or more, 25 seconds or more, or 30 seconds or more, and may be 30 seconds or less, 25 seconds or less, or 20 seconds or less.

The prescribed charging speed may be 3C or more, 4C or more, or 5C or more, and may be 5C or less, 4C or less, or 3C or less.

### <Method for Estimating Battery SOC>

The method of the present disclosure for estimating battery SOC comprises, after step (b), having a computer execute the following steps: (i) determining an estimated amount of change in SOC associated with battery degradation from the estimated battery capacity based on a pre-specified second relationship between the estimated battery capacity and an amount of change in SOC associated with battery degradation, or (ii) determining an estimated SOC after change associated with battery degradation from the estimated battery capacity based on a pre-specified third specific relationship between the estimated battery capacity and SOC after change associated with battery degradation.

As described above, techniques for estimating SOC based on OCV of a battery are known. In this regard, the present disclosers have found that a difference occurs between the SOC estimated in relation to OCV of a battery and the actual SOC due to battery degradation associated with degradation of the positive and negative electrodes caused by charging and discharging, that is, due to a decrease in battery capacity, for example. In other words, the present disclosers have found that SOC may change due to battery degradation.

In this regard, the present disclosers have found that based on the pre-specified relationship between the estimated battery capacity and the amount of change in SOC or SOC after change associated with battery degradation, it is possible to determine the estimated amount of change in SOC or the estimated SOC after change associated with battery degradation from the estimated battery capacity.

The method of the present disclosure for estimating SOC of a battery is particularly valid in a battery whose SOC changes mainly due to deterioration of positive and negative electrodes, such as a solid-state battery. The “solid-state battery” relating to the present disclosure means a battery using at least a solid electrolyte as the electrolyte, and therefore the solid-state battery may use a combination of a solid electrolyte and a liquid electrolyte as the electrolyte. In addition, the solid-state battery of the present disclosure may be an all-solid-state battery, i.e., a battery using only a solid electrolyte as the electrolyte.

The method of the present disclosure for estimating battery capacity and SOC may be executed by a system that estimates battery capacity and SOC. This system comprises ECU. A typical configuration of ECU comprises at least a ROM (Read Only Memory) that stores a program for executing such control, a CPU (Central Processing Unit) that can execute the program, a RAM (Random Access Memory) that temporarily stores data, and input-output port.

Various signals from a voltage sensor, a current sensor, a temperature sensor or the like are input to the ECU via an input port. Further, from ECU, drive signals to loads (power consumption machine and/or power supplying machine), or the like are output from the ECU via an output port.

The ECU comprises a means determining the provisional SOC, a means for acquiring the specific internal resistance, and a means for acquiring the estimated battery capacity, as well as a means for acquiring the amount of change in SOC or a means for acquiring the SOC after change.

The means determining the provisional SOC is configured to determine whether the provisional SOC is 80% or more. The method for determining whether the provisional SOC is 80% or more is not particularly limited. For example, a conventionally known methods conventionally used in general battery systems may be adopted as a method for determining whether the measured value is more than or equal to a threshold value.

The means for acquiring the specific internal resistance is configured to acquire (estimate) the specific internal resistance. The method for acquiring the specific internal resistance is not particularly limited, and a conventionally known methods conventionally used in general battery systems may be adopted. For example, a method for estimating the specific internal resistance by dividing the amount of voltage change during charging and discharging by the amount of current change at that time based on various data detected by a voltage sensor and a current sensor (e.g., a method for linearly approximating a parameter of the amount of current change and a parameter based on the amount of voltage change and the amount of impedance change, and calculating the slope of the approximated straight line as the impedance of the battery) is exemplified.

The means for acquiring the specific internal resistance can determine the specific internal resistance when charging at a prescribed charging speed for a prescribed time at a prescribed provisional SOC of 80% or more and at a temperature.

The means for acquiring the estimated battery capacity is configured to acquire the estimated battery capacity. The estimated battery capacity can be determined from the specific internal resistance based on a pre-specified first relationship between the specific internal resistance and the battery capacity. Here, the first relationship may be, for example, a map showing the relationship between the specific internal resistance and the battery capacity.

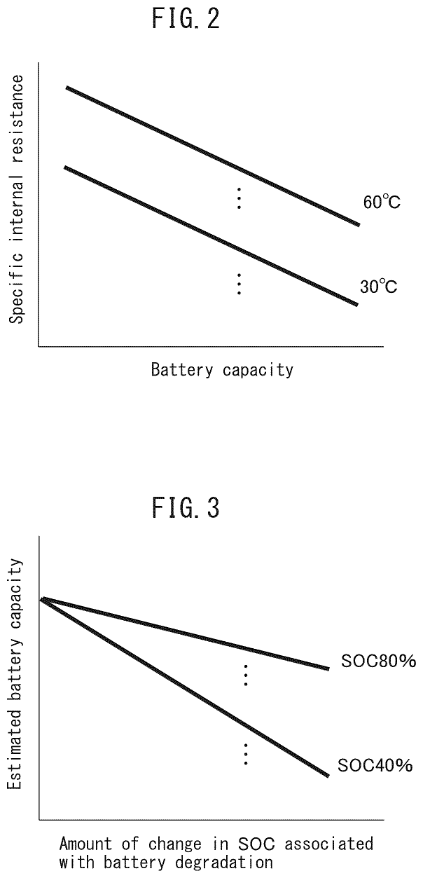

FIG. 2 is an example of a map showing the relationship between the specific internal resistance and the battery capacity. The map may be prepared in advance by plotting the specific internal resistance acquired by the means for acquiring the specific internal resistance and the battery capacity. This map can be prepared for each temperature at which charging is executed.

The battery capacity may be acquired by an optional means for acquiring the battery capacity. The method for acquiring the battery capacity is not particularly limited, and a conventionally known methods conventionally used in general battery systems may be adopted. For example, a method for acquiring the battery capacity of a secondary battery according to a battery model formula based on various data detected by a voltage sensor, a current sensor, and a temperature sensor or the like, (e.g., a method for acquiring the battery capacity of a secondary battery by storing the pre-determined open circuit voltage characteristics of a positive electrode and a negative electrode of the secondary battery, extracting the amount of active material of the positive electrode and the negative electrode, capacity density, and resistance value by referring to this stored data, and the data detected by a voltage sensor, a current sensor, and a temperature sensor, and using the extracted parameters) is exemplified.

The means for acquiring the estimated battery capacity can derive the estimated battery capacity by having the ECU execute a process of substituting the specific internal resistance acquired by the means for acquiring the specific internal resistance into a primary formula configuring the prepared map.

The means for acquiring the amount of change in SOC is configured to acquire the amount of change in SOC associated with battery degradation. The amount of change in SOC associated with battery degradation can be determined from the estimated battery capacity based on a pre-specified second relationship between the estimated battery capacity and the amount of change in SOC associated with battery degradation. Here, the second relationship may be, for example, a map showing the relationship between the estimated battery capacity and the amount of change in SOC associated with battery degradation.

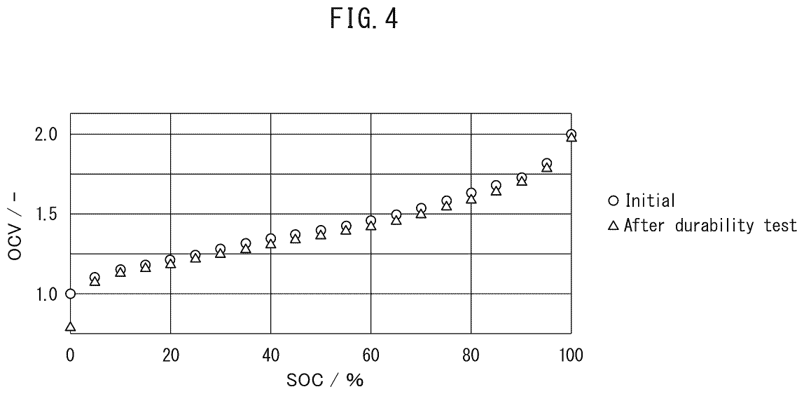

FIG. 3 is an example of a map showing the relationship between the estimated battery capacity and the amount of change in SOC associated with battery degradation. This map may be prepared in advance by plotting the estimated battery capacity and the amount of change in SOC associated with battery degradation. The amount of change in SOC associated with battery degradation in this map can be determined, for example, by subjecting a battery to a general durability test, preparing an SOC-OCV curve before and after the durability test as shown in FIG. 4, and calculating the difference in SOC before and after the durability test for the same OCV. In addition, during the durability test described above, by also measuring the battery capacity and by plotting the relationship between the measured battery capacity and the calculated amount of change in SOC, the map can be prepared. This map can be prepared for each SOC. In FIG. 4, the OCV value is shown as a relative value with the value before the durability test (initial) when SOC is 0 being taken as 1.0.

The means for acquiring the amount of change in SOC can derive the amount of change in SOC associated with battery degradation by having ECU execute a process of substituting the estimated battery capacity acquired by the means for acquiring estimated battery capacity into a primary formula configuring the prepared map.

The means for acquiring the SOC after change is configured to acquire the SOC after change associated with battery degradation. The SOC after change associated with battery degradation can be determined from the estimated battery capacity based on a pre-specified third relationship between the estimated battery capacity and the SOC after change associated with battery degradation. Here, the third relationship may be, for example, a map showing the relationship between the estimated battery capacity and SOC after change associated with battery degradation.

In this method, the map showing the relationship with the estimated battery capacity may be prepared in advance. The SOC after change associated with battery degradation in this map may be, for example, the SOC after a general durability test for the battery. Further, during the durability test described above, by also measuring the battery capacity and by plotting the relationship between the measured battery capacity and the SOC after change associated with battery degradation, the map can be prepared. This map can be prepared for each SOC.

The means for acquiring the SOC after change can derive the SOC after charge by having ECU execute a process of substituting the estimated battery capacity acquired by the means for acquiring estimated battery capacity into a primary formula configuring the prepared map.

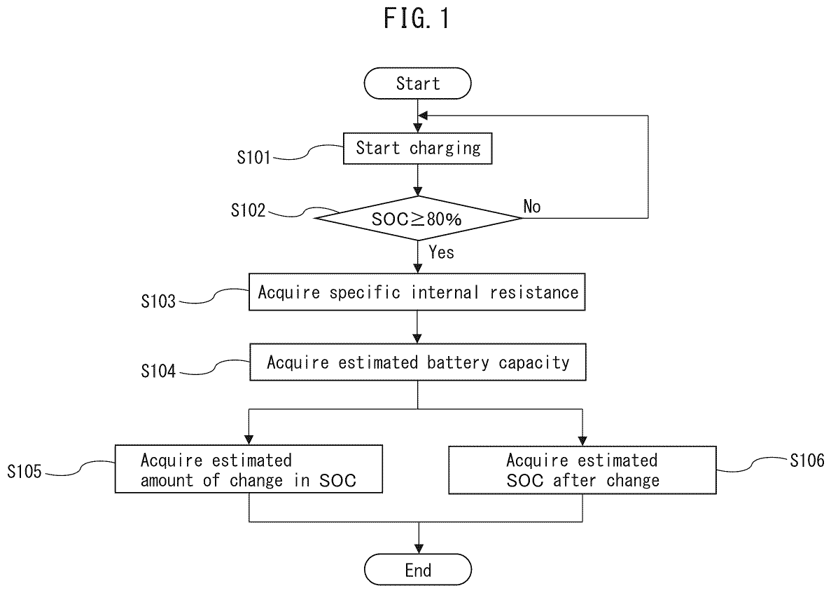

The method for the present disclosure for estimating battery capacity and battery SOC will be described using the flow chart shown in FIG. 1.

In S101, ECU starts charging a battery.

In S102, by the means determining the provisional SOC, ECU determines whether the provisional SOC is 80% or more. If the provisional SOC is 80% or more, ECU executes the process of S103. If the provisional SOC is less than 80%, ECU executes the process of S101 again.

In S103, by the means for acquiring the specific internal resistance, ECU acquires the specific internal resistance when the battery is charged under a prescribed condition. The specific internal resistance can be calculated based on the voltage and current of the battery during charging. ECU can acquire the voltage of the battery based on the output of the voltage sensor. ECU can also current the current of the battery based on the output of the current sensor.

In S104, by the means for acquiring the estimated battery capacity, ECU determines the estimated battery capacity from the specific internal resistance acquired in S103 based on, for example, a map showing the relationship between the specific internal resistance and the battery capacity. Here, the map showing the relationship between specific internal resistance and battery capacity can be prepared in advance and stored in ROM. In this case, ECU can determine the estimated battery capacity by executing a process of substituting the specific internal resistance acquired in S103 into a primary formula configuring the above map read from the ROM.

Since the internal resistance of a battery may change depending on the temperature of the battery, if information showing the relationship between the internal resistance and the temperature of the battery is acquired in advance, it is possible to acquire the internal resistance corresponding to this temperature by acquiring the temperature of the battery. The temperature of the battery can be acquired using a temperature sensor. Information showing the relationship between the internal resistance and temperature of the battery can be stored in ROM. The information showing the relationship between the internal resistance and the temperature of the battery can be expressed as a map or a function.

In S105, by means for acquiring the amount of change in SOC, ECU can determine the amount of change in SOC associated with battery degradation from the estimated battery capacity determined in S104 based on, for example, a map showing the relationship between the battery capacity and the amount of change in SOC associated with battery degradation. Here, the map showing the relationship between the battery capacity and the amount of change in SOC associated with battery degradation can be prepared in advance and stored in ROM. In this case, ECU can determine the estimated amount of change in SOC associated with battery degradation by executing the process of substituting the estimated battery capacity acquired in S104 into a primary formula configuring the above map read from the ROM.

In S106, by the means for acquiring the SOC after change, ECU can acquire the estimated SOC after change associated with battery degradation from the estimated battery capacity determined in S104 based on a map showing the relationship between the battery capacity and SOC after change associated with battery degradation. Here, the map showing the relationship between the battery capacity and SOC after change associated with battery degradation can be prepared in advance and stored in ROM. In this case, ECU can determine the estimated SOC after change associated with battery degradation by executing the process of substituting the estimated battery capacity acquired in S104 into a primary formula configuring the above map read from the ROM.

The battery SOC can be estimated by S105 or S106.

According to the SOC estimated by the method of the present disclosure, for example, the output value of battery can be controlled with high precision based on a map prepared for each temperature showing the relationship between the SOC estimated by the method of the present disclosure and the output value of battery. For example, if changes in SOC associated with battery degradation are not taken into consideration, the output value based on the above map may differ from the actual value. In contrast, the SOC estimated by the method of the present disclosure can output an actual value.

1. A method for estimating battery capacity, comprising having a computer execute the following steps:
(a) determining a specific internal resistance by charging at a prescribed charging speed for a prescribed time at a prescribed provisional SOC of 80% or more and at a prescribed temperature; and
(b) determining an estimated battery capacity from the specific internal resistance based on a pre-specified first relationship between the specific internal resistance and battery capacity.

2. A method for estimating battery SOC, comprising, after step (b) in the method according to claim 1, having a computer execute the following steps:
(i) determining an estimated amount of change in SOC associated with battery degradation from the estimated battery capacity based on a pre-specified second relationship between the estimated battery capacity and an amount of change in SOC associated with battery degradation, or
(ii) determining an estimated SOC after change associated with battery degradation from the estimated battery capacity based on a pre-specified third specific relationship between the estimated battery capacity and SOC after change associated with battery degradation.

3. The method according to claim 1,
wherein the first relationship has a primary formula, and
wherein coefficient of determination of the primary formula is 0.8 or more,

4. The method according to claim 1,
wherein the prescribed time is 20 seconds or more, and
wherein the prescribed charging speed is 3C or more.
